(19) United States
(12) Patent Application Publication
(10) Pub. No.: US 2014/0017837 A1
(43) Pub. Date: Jan. 16, 2014

(54) METHOD OF CUTTING SILICON SUBSTRATE HAVING LIGHT-EMITTING ELEMENT PACKAGE

(71) Applicant: SAMSUNG ELECTRONICS CO., LTD., Suwon-si (KR)

(72) Inventors: Eui-seok KIM, Gyeonggi-do (KR); Choo-ho Kim, Gyeonggi-do (KR); Soo-Hyun Cho, Gyeonggi-do (KR); Won-soo Ji, Gyeonggi-do (KR)

(73) Assignee: SAMSUNG ELECTRONICS CO., LTD., Suwon-si (KR)

(21) Appl. No.: 13/844,742

(22) Filed: Mar. 15, 2013

(30) Foreign Application Priority Data
Jul. 13, 2012 (KR) 10-2012-0076939

(51) Int. Cl. H01L 33/48

(52) U.S. Cl. CPC H01L 33/48
USPC 438/33

(57) ABSTRACT

Methods of cutting silicon substrates having a light-emitting element package. The method includes preparing a silicon substrate on which a plurality of light-emitting element chips are mounted and a transparent material layer that covers the light-emitting element chips is formed; removing the transparent material layer between the light-emitting element chips along a predetermined cutting line by using a mechanical cutting method; forming a scribing line corresponding to the predetermined cutting line on the silicon substrate by using a laser processing method; and cutting the silicon substrate to form individual light-emitting element packages by applying a mechanical impact to the silicon substrate along the scribing line. The method may enhance productivity of a cutting process of light-emitting element packages, and may prevent damage or transformation of the transparent material layer.

### CROSS-REFERENCE TO RELATED APPLICATIONS

This application claims the benefit of priority to Korean Patent Application No. 10-2012-076939, filed on Jul. 13, 2012, in the Korean Intellectual Property Office, the disclosure of which is incorporated herein in their entirety by reference.

### TECHNICAL FIELD

The present disclosure relates to a method of cutting silicon substrates having light-emitting element packages.

### BACKGROUND

Light-emitting diodes (LEDs) are semiconductor devices that emit various light colors by configuring a light source through a PN junction of compound semiconductors. LEDs have various merits, such as a long lifetime, miniaturization, and driving at a low voltage due to high directionality. Also, LEDs are less susceptible impact and vibration, do not require a preheating time and a complicated driving, and may be packaged in various types. Accordingly, LEDs may be applied for various purposes.

An LED chip such as an LED light-emitting diode is manufactured in a light-emitting element package type through a packaging process in which elements are mounted on a lead frame and a mold frame.

Since high-power LED products have been developed, a package capable of effectively radiating heat generated during operation is required. To this end, methods using a ceramic substrate, using a silicon substrate, or using a substrate formed of silicon and AlN have been proposed.

In the case of using a ceramic substrate, the ceramic substrate has a high thermal resistance compared to other substrates, and thus, the range of the usable voltages is considerably limited. In the case of using a substrate formed of silicon and AlN, the high raw material price of AlN results in an increase in the manufacturing cost of the light-emitting element package.

After a packaging process, a cutting process is necessary to divide a plurality of light-emitting element packages into individual light-emitting element packages. The cutting process, for example, uses a blade sawing method, which cut the light-emitting element packages by using a rotating blade wheel. However, the material of the silicon substrate is not a material that is easily cut compared to a transparent material layer formed on the light-emitting element chips, and thus, a cutting productivity is very low. Therefore, a need exists for a number of sawing blades in order to increase cutting productivity.

### SUMMARY

The present disclosure encompasses methods of increasing a cutting productivity of a cutting process for cutting light-emitting element packages that employ silicon substrates.

Additional aspects will be set forth in part in the description which follows and, in part, will be apparent from the description, or may be learned by practice of the presented embodiments.

An aspect of the present disclosure provides a method of cutting a light-emitting element package. The method includes preparing a silicon substrate on which a plurality of light-emitting element chips are mounted and a transparent material layer that covers the plurality of light-emitting element chips is formed; removing the transparent material layer between the plurality of light-emitting element chips along a predetermined cutting line by using a mechanical cutting method; forming a scribing line corresponding to the predetermined cutting line on the silicon substrate by using a laser processing method; and cutting the silicon substrate to form individual light-emitting element packages by applying a mechanical impact to the silicon substrate along the scribing line.

The transparent material layer may be formed by using a transfer molding method.

The mechanical cutting method may be one of a blade sawing method, a water-jet method, and an aerosol jet method.

The mechanical cutting method may include cutting the silicon substrate to a depth of less than about 50 μm from a surface of the silicon substrate on which the plurality of light-emitting element chips are mounted.

The laser processing method may include a half-cutting method in whichwhich cut a portion of the thickness of the silicon substrate is cut.

The laser processing method may include irradiating a laser beam onto a surface opposite to the a surface of the silicon substrate on which the light-emitting element chips are mounted.

The laser processing method may include a laser ablation method in which cutting begins from a outer surface of the silicon substrate.

The silicon substrate may be cut with a depth of less than about 50 μm from a surface opposite to a surface of the silicon substrate on which the light-emitting element chips are mounted.

The scribing line may be formed on a the outer surface of the silicon substrate.

The scribing line may be formed on a surface opposite to a surface of the silicon substrate on which the light-emitting element chips are formed.

The laser processing method may include a laser stealth method in which a crack is generated within the silicon substrate.

The scribing line may be formed within the silicon substrate.

The separating of the silicon substrate to form individual light-emitting element packages may include applying a mechanical impact onto a surface of the silicon substrate on which the light-emitting element chips are mounted.

The separating of the silicon substrate to form individual light-emitting element packages may include applying a mechanical impact onto a surface opposite to a surface of the silicon substrate on which the light-emitting element chips are formed.

The transparent material layer may include a transparent silicon group polymer.

According to the present disclosure, in a light-emitting element package that includes a silicon substrate, a transparent material layer that is not adequate for processing with a laser is cut by using a mechanical cutting method and a scribing line is formed on the silicon substrate by irradiating a high output laser beam. Afterwards, individual light-emitting element packages are formed by cutting the silicon substrate by applying a mechanical impact. Accordingly, productivity of cutting process may be enhanced and damage to or transformation of the transparent material layer may be avoided.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a light-emitting element package manufactured by a cutting method according to an embodiment of the present disclosure;

FIG. 2 is a cross-sectional view of a light-emitting element package manufactured by a cutting method according to an embodiment of the present disclosure;

FIG. 3 is a cross-sectional view of a light-emitting element package manufactured by a cutting method according to an embodiment of the present disclosure;

FIG. 4 is a is a cross-sectional view of a light-emitting element package manufactured by a cutting method according to an embodiment of the present disclosure;

FIG. 5 is a cross-sectional view of a transparent material layer on a plurality of light-emitting element chips formed on a silicon substrate;

FIG. 6 is a cross-sectional view showing a method of removing a transparent material layer by using a blade sawing method;

FIG. 7 is a cross-sectional view showing a method of forming a scribing line on a second surface of a silicon substrate by irradiating a laser beam onto the silicon substrate;

FIG. 8 is a partial perspective view showing a method of forming a scribing line on a second surface of a silicon substrate by using the method shown in FIG. 7;

FIG. 9 is a cross-sectional view showing a method of forming a scribing line in a silicon substrate by irradiating a laser beam onto the silicon substrate; and

FIGS. 10 and 11 are cross-sectional views showing a method of cutting a silicon substrate according to a scribing line by using a breaking blade.

### DETAILED DESCRIPTION

Reference will now be made in detail to embodiments, examples of which are illustrated in the accompanying drawings. In the drawings, like reference numerals refer to like elements throughout, and the thicknesses of layers and sizes of elements may be exaggerated for clarity.

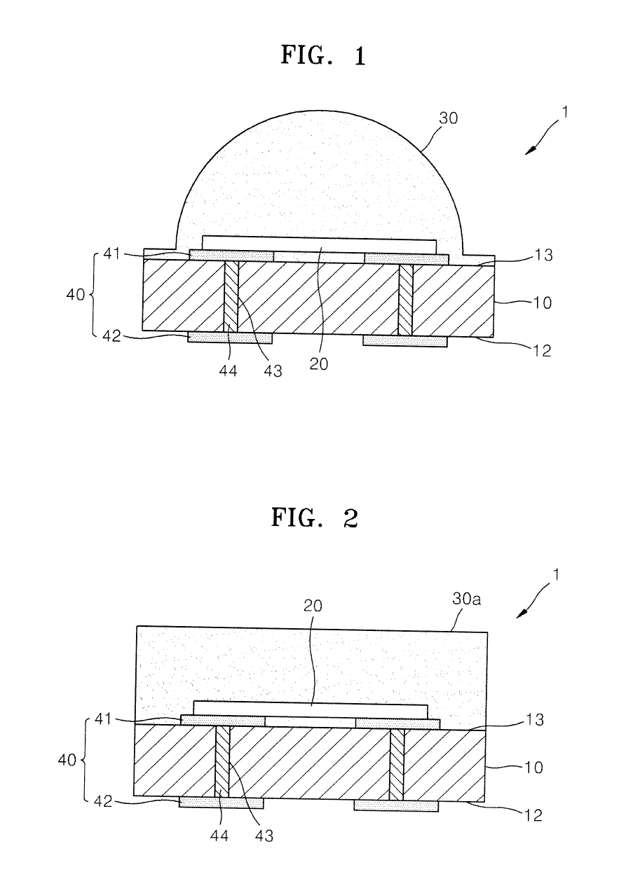

FIG. 1 is a cross-sectional view of a light-emitting element package 1 manufactured by a cutting method according to an embodiment of the present disclosure. Referring to FIG. 1, the light-emitting element package 1 may include a silicon substrate 10, a light-emitting element chip 20 mounted on the silicon substrate 10, and a transparent material layer 30 covering the light-emitting element chip 20.

The light-emitting element chip 20 may be, for example, a light-emitting diode (LED) chip. The LED chip may emit a blue, green, or red color according to the material of a compound semiconductor that constitutes the LED chip. For example, a blue color emitting LED chip may include an active layer having a plurality of quantum well structures in which GaN and InGaN are alternately disposed, and a p-type clad layer and an n-type clad layer, which are formed of a compound semiconductor of AlₓGa_{y}N_{z}, on and under the active layer. Also, the LED chip may emit colorless ultraviolet rays. In the current embodiment, the light-emitting element chip 20 is an LED chip, but the present disclosure is not limited thereto. For example, the light-emitting element chip 20 may be a UV optical diode chip, a laser diode chip, or an organic light-emitting diode chip.

The silicon substrate 10 includes silicon as a main component, and may be formed by actively applying a micro electro-mechanical system processing technique to silicon. Also, the silicon substrate 10 may be formed by using silicon semiconductor manufacturing techniques, such as, mass production techniques, integration techniques, and wafer level package (WLP) techniques. Thus, the silicon substrate 10 may be implemented in a miniaturized and multi-dimensional array structure. Also, the silicon substrate 10 has a thermal resistance less than that of a conventional ceramic substrate, and a manufacturing cost may be reduced because expensive AlN is not used.

A circuit pattern 40 is formed on the silicon substrate 10. The circuit pattern 40 may include first and second circuit patterns 41 and 42 respectively formed on a first surface 13 of the silicon substrate 10 on which the light-emitting element chip 20 is mounted and a second surface 12(or outer surface) which is opposite to the first surface 13. The first and second circuit patterns 41 and 42 may be connected to each other via a via hole 43 formed through the silicon substrate 10. For example, the first and second circuit patterns 41 and 42 may be electrically connected to each other by a conductive material 44 filled in the via hole 43. The first and second circuit patterns 41 and 42 may be formed by applying a conductive material on the first and second surfaces 13 and 12 using a printing method or a plating method. The first circuit pattern 41 may include two patterns respectively corresponding to an anode electrode (not shown) and a cathode electrode (not shown) of the light-emitting element chip 20.

The transparent material layer 30 covers the light-emitting element chip 20 to protect the light-emitting element chip 20, and may have functions of controlling a directionality and color of light emitted from the light-emitting element chip 20. The transparent material layer 30 may be formed of a transparent material, for example, a transparent silicon group polymer so that light emitted from the light-emitting element chip 20 may pass through. Here, the silicon group polymer is a generic term for organic compound siloxane polymer homologues that contains silicon.

When the transparent material layer 30 has a function of controlling a directionality of light, as depicted in FIG. 1, the transparent material layer 30 may have a lens shape. The transparent material layer 30 may have various shapes, such as a concave lens shape or a convex lens shape according to the application filed of the light-emitting element package 1. In FIG. 1, the transparent material layer 30 having a lens shape is depicted. However, the transparent material layer 30 may have various shapes, for example, as depicted in FIG. 2, may have a flat shape.

In the current embodiment, the transparent material layer 30 is a monolayer, but the present invention is not limited thereto. For example, the transparent material layer 30 may be a double layer that includes a phosphor layer in which a phosphor is included to control a color of light emitted from the light-emitting element chip 20 and a protection layer that covers the phosphor layer and the light-emitting element chip 20. Also, the protection layer may have a lens shape. Besides the above, the transparent material layer 30 may have a multi-layer structure having more than three layers according to the application field of the light-emitting element package 1.

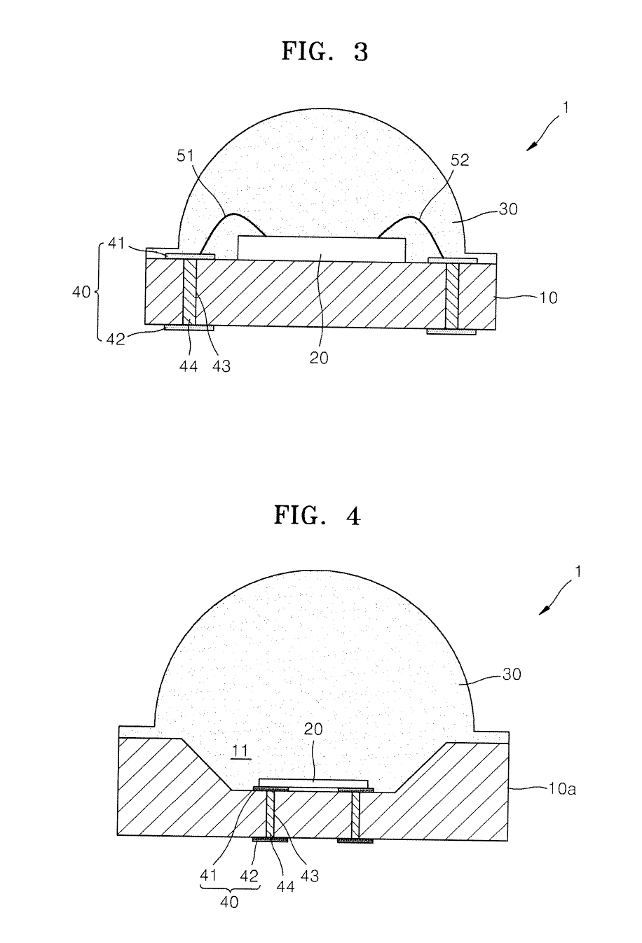

In FIG. 1, the anode electrode (not shown) and the cathode electrode (not shown) of the light-emitting element chip 20 are directly electrically connected to the first circuit pattern 41 formed on the first surface 13 of the silicon substrate 10, but the present disclosure is not limited thereto. As depicted in FIG. 3, the light-emitting element chip 20 is directly mounted on the silicon substrate 10, and the anode electrode (not shown) and the cathode electrode (not shown) of the light-emitting element chip 20 may be connected to the first circuit pattern 41 via conductive wires 51 and 52. Although not shown, one of the anode electrode (not shown) and the cathode electrode (not shown) of the light-emitting element chip 20 may be directly electrically connected to the first circuit pattern 41 and the other one may be connected to the first circuit pattern 41 via a conductive wire.

Also, as depicted in FIG. 4, the silicon substrate 10a may include a cavity 11 formed by being sunken in a short period of time by means of an MEMS processing technique. The light-emitting element chip 20 is mounted on a lower bottom surface of the cavity 11. Both side surfaces of the cavity 11 are upwardly inclined to emit light generated from the light-emitting element chip 20 to the outside, and thus, optical efficiency may be increased. Side surfaces of the cavity 11 may be reflection surfaces.

In the light-emitting element package 1 according to the current embodiment, a heat radiation area may be increased by the silicon substrate 10 having a high heat radiation characteristic, and thus, heat generated during an operation of the light-emitting element package 1 may be effectively dissipated.

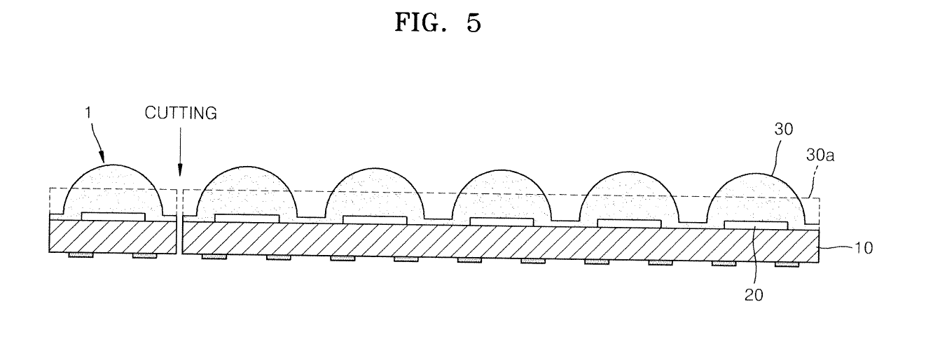

FIG. 5 is a cross-sectional view of the transparent material layer 30 on a plurality of light-emitting element chips 20 formed on the silicon substrate 10. Referring to FIG. 5, the light-emitting element package 1 is formed such that, after mounting a plurality of light-emitting element chips 20 on the silicon substrate 10 and forming the transparent material layer 30 on the light-emitting element chips 20. The individual light-emitting element chip 20 is formed by cutting the transparent material layer 30 and the silicon substrate 10. However, the transparent material layer 30 is formed between the light-emitting element chips 20 in the process of forming the transparent material layer 30 on the light-emitting element chips 20. For example, the transparent material layer 30 may be formed by using a transfer molding method. The transfer molding method is one of simple methods of forming the transparent material layer 30 in a desired shape. In the transfer molding method, a molding (not shown) that covers the silicon substrate 10 on which the light-emitting element chips 20, and of which inside has the desired shape, are formed, a transparent material is injected into the molding and the transparent material is hardened. Afterwards, the transparent material layer 30 is formed by removing the molding.

As described above, when the transparent material layer 30 is formed between the light-emitting element chips 20, it needs to cut the transparent material layer 30 in addition to cutting the silicon substrate 10 between the light-emitting element chips 20 to manufacture the light-emitting element package 1.

As a cutting process for cutting the transparent material layer 30 and the silicon substrate 10, a full-cutting method employs a mechanical cutting which cut the silicon substrate 10 by using a blade wheel. However, this method incurs costs for replacing a lot of blade wheels because the blade wheel wears remarkably with respect to the silicon substrate 10. Yield of the light-emitting element package 1 may be reduced due to particles generated in a mechanical process. Also, gaps between the light-emitting element chips 20 may vary according to the thickness of the blade wheel. The blade wheels used in the full-cutting method should have a large thickness in consideration of the wearing of the blade wheel. Therefore, it is difficult to increase the integrity of the light-emitting element packages 1.

A laser beam cutting method may be considered instead of the mechanical cutting method. The cutting process that uses a laser beam may realize a rapid cutting speed, whereas the object to be cut needs a single material. That is, it is necessary to select a laser beam having a single absorbency with respect to the material to be cut. Accordingly, when a material to be cut includes plural material layers different from each other, cutting may be impossible or cutting speed may be very slow. Also, when the wavelength of the laser beam is changed during the cutting process to address the problems related to the plural layers, the configuration of the cutting apparatus may become very complicated and the reduction of cutting speed may be accompanied.

In the case of the light-emitting element package 1 in which the silicon substrate 10 is employed, the transparent material layer 30 and the silicon substrate 10 need to be cut. When the condition of the laser beam is controlled to cut the silicon substrate 10, the transparent material layer 30 may become melt or burned, and thus, the physical properties of the transparent material layer 30 may be changed. This problem may also occur when the transparent material layer 30 has a flat shape, as indicated by a dashed line in FIG. 5.

In order to solve the problem described above and to accomplish a rapid cutting speed, in the method of cutting the light-emitting element package 1 according to the present disclosure, before performing a cutting process by using a laser beam, the transparent material layer 30 is cut by using a mechanical cutting method, and afterwards, a scribing line S is formed on the silicon substrate 10 using a laser beam, and the silicon substrate 10 is broken by applying a mechanical impact onto the scribing line S to cut the light-emitting element package 1.

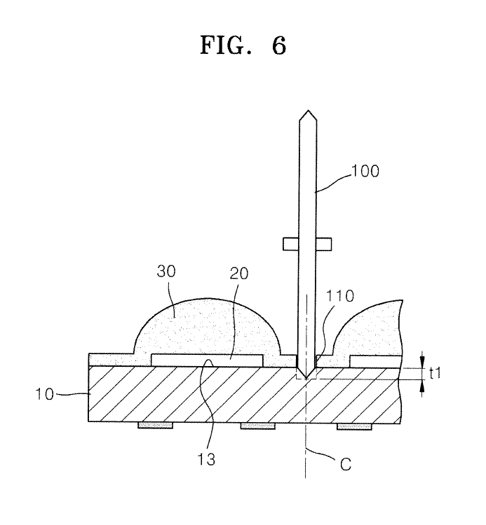

Referring to FIG. 6, the transparent material layer 30 is cut in advance by using a mechanical cutting apparatus, for example, a blade wheel 100 along a predetermined cutting line C between the light-emitting element chips 20. Then, a removing groove 110 from which the transparent material layer 30 is removed is formed along the predetermined cutting line C. The removing groove 110 may be formed largely enough to remove an unnecessary part of the transparent material layer 30 between the light-emitting element chips 20. In order to remove the transparent material layer 30, the mechanical cutting may be performed to a predetermined depth in the silicon substrate 10. In consideration of wearing of the blade wheel 100 and the easiness of the breaking process, the silicon substrate 10 may be cut with a depth t1 of about 50 μm or less from the first surface 13 of the silicon substrate 10 on which the light-emitting element chips 20 are mounted.

The mechanical cutting apparatus is not limited to the blade wheel 100, and may be any mechanical cutting apparatus that may cut the transparent material layer 30 without changing the physical properties of the transparent material layer 30, for example, a water-jet cutting apparatus or an aerosol-jet cutting apparatus. As described above, since the transparent material layer 30 is formed of a transparent resin material, cutting the transparent material layer 30 is easy. Thus, although a mechanical cutting process is employed, a high speed cutting may be realized.

Next, a portion of the silicon substrate 10 may be processed by irradiating a high output laser beam L onto the silicon substrate 10. A wavelength range of the high output laser beam L is controlled so that energy of the laser beam is absorbed in the silicon substrate 10. The processing of a portion of the silicon substrate 10 may be performed by a half-cutting method in which the portion of the silicon substrate 10 is melt and vaporized by the high output laser beam L. In the current embodiment, for convenience of explanation, after cutting the transparent material layer 30, the high output laser beam L is irradiated onto the silicon substrate 10. However, the sequence of operation is not limited thereto, and the irradiation of the high output laser beam L onto the silicon substrate 10 may be performed before performing the cutting of the transparent material layer 30.

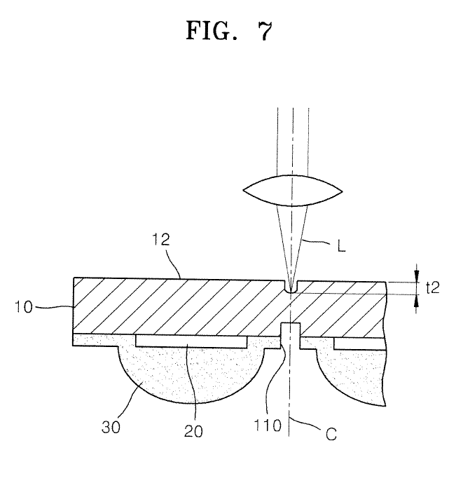

As an example of the laser processing method, as depicted in FIG. 7, a portion of the silicon substrate 10 may be cut by irradiating the high output laser beam L onto the second surface 12 of the silicon substrate 10 on which the transparent material layer 30 is not formed by turning the silicon substrate 10 upside down. This process prevents the thermal effect caused by the high output laser beam L from being influenced on the transparent material layer 30, and thus, damage or deformation of the transparent material layer 30 may be prevented.

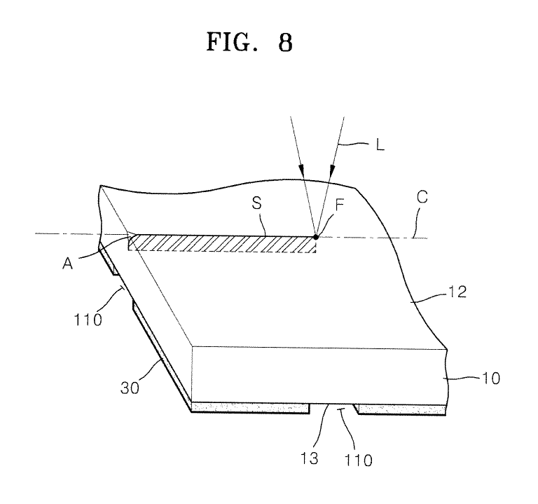

An example of processing the silicon substrate 10 by using a high output laser beam L is a laser ablation method. In this method, as depicted in FIG. 8, a focal center of the high output laser beam L is formed on the second surface 12 of the silicon substrate 10 to cut away the silicon substrate 10 from the second surface 12 in a thickness direction. The high output laser beam L may form a single spot F or plural beam spots F on the second surface 12 of the silicon substrate 10. When plural beam spots F are formed on the second surface 12 of the silicon substrate 10, the plural beam spots F may be arranged in a series in a processing direction, that is, in a relative moving direction between the high output laser beam L and the silicon substrate 10. Also, the plural beam spots F may be separated from each other or some of them may overlap. The beam spots F may have a circular shape or an oval shape having a long axis in a processing direction.

The high output laser beam L is irradiated onto the second surface of the silicon substrate 10 along the predetermined cutting line C. Energy of the high output laser beam L may be set not to melt or evaporate a portion of the silicon substrate 10. The portion of the second surface 12 of the silicon substrate 10 heated by the high output laser beam L, that is, the portion of the silicon substrate 10 where the beam spot F is passed, tends to expand due to increased temperature. However, surroundings of the beam spot F are not heated, and thus, the silicon substrate 10 is obstructed from expansion. Accordingly, in the silicon substrate 10 where the beam spot F passes, a compressive stress is generated locally in a radius direction and a tensile stress is generated in a direction perpendicular to the radius direction. The energy of the high output laser beam L is controlled to control the tensile strength not to exceed the threshold value of the silicon substrate 10. When the silicon substrate 10 is cooled after the beam spot F has passed, the silicon substrate 10 contracts. At this point, cracks occur in the second surface 12 of the silicon substrate 10 while the tensile strength is amplified. The crack may extend to a predetermined distance from the second surface 12 of the silicon substrate 10 in a thickness direction. However, the crack may not extend to the entire thickness of the silicon substrate 10. A scribing line S may be formed on the second surface 12 of the silicon substrate 10 by irradiating a high output laser beam L onto the second surface 12 of the silicon substrate 10 along the predetermined cutting line C by the process described above. The scribing line S may have a depth t2 (refer to FIG. 7) of less than about 50 μm in the thickness direction of the silicon substrate 10 from the second surface 12 of the silicon substrate 10.

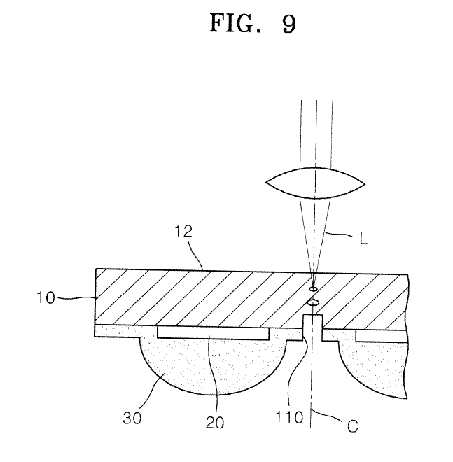

As depicted in FIG. 9, a laser stealth method may be used as another example of processing the silicon substrate 10 by using the high output laser beam L. In this method, plural cracks are formed in the silicon substrate 10 in the thickness direction by forming a focus of the high output laser beam L within the silicon substrate 10. In this way, a scribing line S may be formed in the silicon substrate 10.

In the current embodiment, the second surface 12 of the silicon substrate 10 where the beam spot F has passed is naturally cooled. However, if necessary, the second surface 12 of the silicon substrate 10 where the beam spot F has passed may be cooled by spraying a cooling fluid on a rear of the beam spot F. Also, before irradiating the high output laser beam L, a notch type groove A (refer to FIG. 8) may be formed at the starting point of the scribing line Sin the second surface 12 of the silicon substrate 10.

In the process described above, the second surface 12 of the silicon substrate 10 is a light-entering surface for irradiating the high output laser beam L. However, the first surface 13 of the silicon substrate 10 may be the light-entering surface. At this point, the high output laser beam L is irradiated onto the first surface 13 of the silicon substrate 10 through the removing groove 110 after forming the removing groove 110 in the transparent material layer 30. However, the thermal effect to the transparent material layer 30 and the light-emitting element chip 20 may be reduced when the second surface 12 of the silicon substrate 10 is used as the light-entering surface.

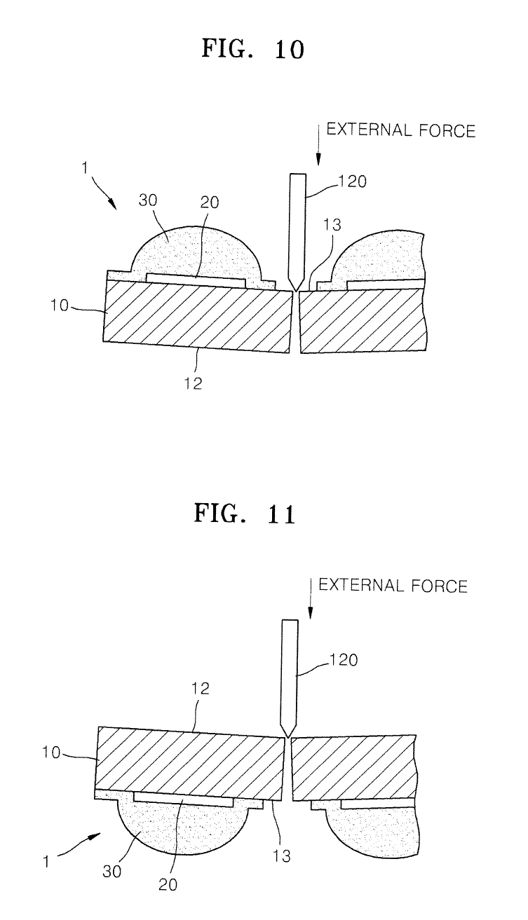

Next, a breaking process is performed to separate the silicon substrate 10 based on the scribing line S. Referring to FIG. 10, when the first surface 13 of the silicon substrate 10, that is, an opposite surface to the second surface 12 of the silicon substrate 10 on which the scribing line S is formed, is pressed by using a breaking blade 120, a crack that forms the scribing line S propagates in the thickness direction of the silicon substrate 10, and thus, the silicon substrate 10 is separated based on the scribing line S. However, the breaking blade 120 is not limited to pressing the first surface 13 of the silicon substrate 10, but, as depicted in FIG. 11, may press the second surface 12 of the silicon substrate 10.

When the scribing line S is formed on the first surface 13 of the silicon substrate 10, the silicon substrate 10 may be separated along the scribing line S by propagating a crack in the thickness direction of the silicon substrate 10, by applying a force onto the first surface 13 or the second surface 12 of the silicon substrate 10, or by using the breaking blade 120.

The light-emitting element package 1 may be formed as a result of the laser scribing process and the breaking process. According to an experiment, the transparent material layer 30 formed of a transparent silicon group polymer to a thickness of approximately 0.1 mm is formed on the silicon substrate 10 having a thickness of approximately 0.5 mm, the removing groove 110 was formed to have a depth of about 50 μm from the first surface 13 of the silicon substrate 10 in the transparent material layer 30 and the silicon substrate 10 by a blade sawing method, and a scribing line S was formed to have a depth of 50 μm from the second surface 12 of the silicon substrate 10 by using a laser ablation method. Afterwards, the silicon substrate 10 is cut to form individual light-emitting element packages 1 by applying a mechanical impact to the silicon substrate 10 using the breaking blade 120.

As described above, in the current embodiment, all the light-emitting element packages 1 are not cut by using a blade sawing method, but a portion of the light-emitting element package 1 is cut with the blade sawing method. Accordingly, the process time for blade sawing, which is a major time consuming process in the conventional cutting method, may be greatly reduced, and thus, cutting speed is also increased. Also, when a full-cutting of the entire light-emitting element package 1 by using a blade sawing method, the blade wheel needs to be replaced after 19 sheet-cuttings of the silicon substrate 10. However, according to the current embodiment, the blade wheel may be replaced after 60 sheet-cuttings of the silicon substrate 10. That is, the replacement period of the blade wheel may be increased to about three times longer than that of the conventional blade sawing method. Accordingly, the maintenance cost of the cutting facility and the time for replacing the blade wheel may be reduced.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A method of cutting a light-emitting element package, the method comprising:
preparing a silicon substrate on which a plurality of light-emitting element chips are mounted and a transparent material layer that covers the plurality of light-emitting element chips is formed;
removing the transparent material layer between the plurality of light-emitting element chips along a predetermined cutting line by using a mechanical cutting method;
forming a scribing line corresponding to the predetermined cutting line on the silicon substrate by using a laser processing method; and
cutting the silicon substrate to form individual light-emitting element packages by applying a mechanical impact to the silicon substrate along the scribing line.

2. The method of claim 1, wherein the transparent material layer is formed by using a transfer molding method.

3. The method of claim 1, wherein the mechanical cutting method is one of a blade sawing method, a water-jet method, and an aerosol jet method.

4. The method of claim 1, wherein the mechanical cutting method comprises cutting the silicon substrate to a depth of less than about 50 pm from a surface of the silicon substrate on which the plurality of light-emitting element chips are mounted.

5. The method of claim 1, wherein the laser processing method comprises a half-cutting method which cut a portion of the thickness of the silicon substrate.

6. The method of claim 1, wherein the laser processing method comprises irradiating a laser beam onto a surface opposite to the surface of the silicon substrate on which the light-emitting element chips are mounted.

7. The method of claim 1, wherein the laser processing method comprises a laser ablation method in which cutting begins from a outer surface of the silicon substrate.

8. The method of claim 7, wherein the silicon substrate is cut with a depth of less than about 50 μm from a surface opposite to a surface of the silicon substrate on which the light-emitting element chips are mounted.

9. The method of claim 7, wherein the scribing line is formed on the outer surface of the silicon substrate.

10. The method of claim 9, wherein the scribing line is formed on the a surface opposite to the a surface of the silicon substrate on which the light-emitting element chips are formed.

11. The method of claim 1, wherein the laser processing method comprises a laser stealth method in which a crack is generated within the silicon substrate.

12. The method of claim 1, wherein the scribing line is formed within the silicon substrate.

13. The method of claim 1, wherein the separating of the silicon substrate to form individual light-emitting element packages comprises applying a mechanical impact onto a surface of the silicon substrate on which the light-emitting element chips are mounted.

14. The method of claim 1, wherein the separating of the silicon substrate to form individual light-emitting element packages comprises applying a mechanical impact onto a surface opposite to a surface of the silicon substrate on which the light-emitting element chips are formed.

15. The method of claim 1, wherein the transparent material layer comprises a transparent silicon group polymer.

16. A method of cutting a light-emitting element package, the method comprising:
forming a plurality of light-emitting element chips on a silicon substrate, and a transparent material layer covering the plurality of light emitting chips;
removing the transparent material layer between the plurality of light-emitting element chips along scribing lines extending between adjacent light emitting element chips among the plurality of the light emitting element chips; and
cutting the silicon substrate to form individual light-emitting element packages by applying a mechanical impact to the silicon substrate along the scribing lines.

17. The method of claim 16, where the removing the transparent layer comprises:
removing the transparent layer between the plurality of light-emitting chips along the scribing lines with a mechanical cutting method; and
irradiating a laser to the silicon substrate along the scribing lines.

18. The method of claim 17, wherein the laser is irradiated onto a surface opposite to the surface of the silicon substrate on which the light-emitting element chips are mounted.

19. The method of claim 16, wherein the scribing lines are formed on the surface of the silicon substrate.

20. The method of claim 16, wherein the scribing lines are formed on the surface opposite to the surface of the silicon substrate on which the light-emitting element chips are formed.
